(19) United States
(12) Patent Application Publication
(10) Pub. No.: US 2016/0124167 A1
(43) Pub. Date: May 5, 2016

(54) TEC INTEGRATED WITH SUBSTRATE

(71) Applicant: FINISAR CORPORATION, Sunnyvale, CA (US)

(72) Inventors: Maziar Amirkiai, Sunnyvale, CA (US); Yu Huang, Sunnyvale, CA (US); Tao Li, Sunnyvale, CA (US); Hongyu Deng, Saratoga, CA (US)

(21) Appl. No.: 14/932,151

(22) Filed: Nov. 4, 2015

Related U.S. Application Data
(60) Provisional application No. 62/075,100, filed on Nov. 4, 2014.

(51) Int. Cl. G02B 6/42; H05K 7/20; B23P 19/04; G02B 6/32; F25B 21/02

(52) U.S. Cl. CPC G02B 6/4271; G02B 6/32; G02B 6/4279; F25B 21/02; B23P 19/04; H05K 7/2039

(57) ABSTRACT

This disclosure generally relates to high-speed fiber optic networks that use light signals to transmit data over a network. The disclosed subject matter includes devices and methods relating to thermoelectric coolers (TECs) and/or optoelectronic subassemblies. In some aspects, the disclosed devices and methods may relate to a TEC having a TEC top, a top layer of an optoelectronic subassembly substrate, and a plurality of pillars extending between the TEC top and the top layer, such that the TEC is devoid of a TEC base between the pillars and optoelectronic subassembly substrate.

### CROSS-REFERENCE TO RELATED APPLICATIONS

This application claims priority to U.S. Provisional Application 62/075,100 filed Nov. 4, 2014, entitled TEC INTEGRATED WITH SUBSTRATE, which is incorporated by reference in its entirety.

### BACKGROUND

The present disclosure relates to high-speed fiber optic networks that use light signals to transmit data over a network. Fiber optic networks have various advantages over other types of networks such as copper wire based networks. Many existing copper wire networks operate at near maximum possible data transmission rates and at near maximum possible distances for copper wire technology. Fiber optic networks are able to reliably transmit data at higher rates over further distances than is possible with copper wire networks.

The claimed subject matter is not limited to configurations that solve any disadvantages or that operate only in environments such as those described above. This background is only provided to illustrate examples of where the present disclosure may be utilized.

### SUMMARY

In one example, a thermoelectric cooler (“TEC”) includes a TEC top, a top layer of an optoelectronic subassembly substrate; and a plurality of pillars extending between the TEC top and the top layer.

In another example, a TEC includes a TEC top, a top layer of an optoelectronic subassembly substrate, and a plurality of pillars extending between the TEC top and the top layer, and the TEC is devoid of a TEC base between the pillars and optoelectronic subassembly substrate.

In yet another example, an optoelectronic assembly includes a TEC integrated with an optoelectronic subassembly substrate with a TEC top, a top layer of the optoelectronic subassembly substrate, and a plurality of pillars extending between the TEC top and the top layer.

In a further example, a method includes providing a TEC top with a plurality of pillars extending from a bottom surface of the top and coupling the pillars with a top layer of an optoelectronic subassembly substrate to form an integrated TEC.

This Summary is provided to introduce a selection of concepts in a simplified form that are further described below in the Detailed Description. This Summary is not intended to identify key features or essential characteristics of the disclosed subject matter, nor is it intended to be used as an aid in determining the scope of the claims. Additional features and advantages will be set forth in the description which follows, and in part will be obvious from the description, or may be learned by practice.

### BRIEF DESCRIPTION OF THE DRAWINGS

FIG. 1 is a top perspective view of an embodiment of an optoelectronic assembly having a thermoelectric cooler (TEC).

FIG. 2 is an alternative top perspective view of the optoelectronic assembly and TEC of FIG. 1.

FIG. 3 is a top view of the optoelectronic assembly and TEC of FIG. 1.

FIG. 4 is a side view of the optoelectronic assembly and TEC of FIG. 1.

FIG. 5 is a side perspective view of the optoelectronic assembly and TEC of FIG. 1.

FIG. 6 is a bottom perspective view of the optoelectronic assembly and TEC of FIG. 1.

FIG. 7A is a bottom perspective view of an embodiment of a TEC.

FIG. 7B is a top perspective view of an embodiment of a TEC.

FIG. 8A is a bottom perspective view of an embodiment of a TEC.

FIG. 8B is a top perspective view of an embodiment of a TEC.

### DETAILED DESCRIPTION

Reference will be made to the drawings and specific language will be used to describe various aspects of the disclosure. Using the drawings and description in this manner should not be construed as limiting its scope. Additional aspects may be apparent in light of the disclosure, including the claims, or may be learned by practice.

The terms and words used in the following description and claims are not limited to the bibliographical meanings, but are merely used to enable a clear and consistent understanding of the disclosure. It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those skilled in the art, may occur in amounts that do not preclude the effect the characteristic was intended to provide.

In this disclosure the term “optoelectronic subassembly” may be used to refer to any portion of an optoelectronic assembly. However, at times this disclosure may use “optoelectronic subassembly” to refer to specific portions of an optoelectronic assembly, as may be indicated by context.

High-speed fiber optic networks use light signals (which may also be referred to as optical signals) to transmit data over a network. Fiber optic networks have various advantages over other types of networks such as copper wire based networks. Many existing copper wire networks operate at near maximum possible data transmission rates and at near maximum possible distances for copper wire technology. Fiber optic networks are able to reliably transmit data at higher rates over further distances than is possible with copper wire networks.

Although fiber optic networks use light signals to carry data, many electronic devices such as computers and other network devices use electrical signals. Accordingly, optoelectronic assemblies may be used to convert electrical signals to optical signals, convert optical signals to electrical signals, or convert both electrical signals to optical signals and optical signals to electrical signals.

Optoelectronic assemblies may include optoelectronic subassemblies (“OSAs”), such as receiver optoelectronic subassemblies (“ROSAs”), transmitter optoelectronic subassemblies (“TOSAs”), or both. A ROSA receives light signals with a light detector such as a photodiode and converts light signals into electrical signals. A TOSA receives electrical signals and transmits corresponding light signals. A TOSA may include an optical transmitter such as a laser that generates light that is transmitted through a fiber optic network. Optoelectronic assemblies or subassemblies may include various components such as optical components and/or electronic components.

Some optoelectronic assemblies may include multiple channels (“multi-channel optoelectronic assemblies”), with each channel corresponding to a set of one or more optical signals travelling through an optical fiber. Multi-channel optoelectronic assemblies may support increased data transfer rates through fiber optic networks. For example, a four channel optoelectronic assembly may be able to send and receive data at data transfer rates of approximately four times the data transfer rate of a comparable single channel optoelectronic assembly.

Optoelectronic assemblies may need to comply with certain standards that may specify aspects of optoelectronic assemblies such as size, power handling, component interfaces, operating wavelengths or other specifications. Examples of such standards include CFP, XAUI, QSFP, QSFP+, XFP, SFP and GBIC. Complying with such standards may limit the structure, size, cost, performance or other aspects of optoelectronic assembly designs. Such standards may also limit configurations of components of optoelectronic assemblies such as receptacles that receive ferrule assemblies and/or hermetic sealing structures such as housings.

Thermoelectric coolers (“TECs”) may be used in optoelectronic assemblies to manage temperatures. For example, TECs may selectively cool or heat all or portions of optoelectronic assemblies. TECs may be used to help maintain a constant temperature of optoelectronic assemblies. Additionally or alternatively, TECs may be used to vary the temperature of optoelectronic assemblies. Additionally or alternately, TECs may increase the range of operating temperatures of optoelectronic assemblies.

In optoelectronic assemblies that include optical transmitters such as lasers, TECs may be used to vary temperatures to control the wavelengths of signals emitted by the lasers. Additionally or alternately, TECs may be used to maintain constant temperatures to stabilize the wavelengths of signals emitted by the lasers. Additionally or alternately, TECs may increase the range of operating temperatures of lasers used in optoelectronic assemblies. Some applications of TECs may be known.

Some optoelectronic assemblies may include hermetically sealed housings to protect components. However, space within hermetically sealed housings may be limited, especially if the optoelectronic assemblies comply with small form factor industry standards such as SFP. Furthermore, increasing the size of hermetically sealed housings may increase the costs of producing optoelectronic assemblies. Conversely, decreasing the size of hermetically sealed housings may decrease the costs of producing optoelectronic assemblies.

In some optoelectronic assemblies, electronic and/or radio frequency signal transmission lines (“RF lines”) may couple lasers or other components of optoelectronic assemblies. The electrical performance of the RF lines (“RF performance” or “RF response”) may be important to the operation optoelectronic assemblies. Accurately controlling and/or reducing the dimensions of RF lines may contribute to optoelectronic assemblies with suitable and/or favorable RF performance. However, the previous design and positioning of components of optoelectronic assemblies, such as TECs, may prevent the length of transmission lines from being sufficiently minimized. The TEC described having a low profile can facilitate minimization of RF lines.

Components such as optoelectronic subassemblies or portions of optoelectronic subassemblies may be produced in large quantities and the produced components may need to comply with specifications that specify various aspects of the produced components (e.g. shape, dimensions and/or positioning). The produced components may include variations in the specifications. Some variation in specifications may be permitted because the produced components may be suitable or work properly. Some variations in specifications may result in components that are unsuitable. Tolerance may refer to an allowable amount of variation of a specification (e.g. dimension or positioning). Some specifications may have higher (“wider”) or lower (“tighter”) tolerance. For example, outside dimensions of optoelectronic subassemblies may have a wider tolerance because the variations may not affect the operation of the produced optoelectronic subassemblies. In another example, the positioning of optical components may require a tighter tolerance because the positioning affects the focus and/or transmission of optical signals. In yet another example, the dimensions of RF lines may require tighter tolerances because the dimensions may significantly affect RF performance.

The selected production processes may affect the prevalence and extent of the variations. In some circumstances the production processes may be controlled to increase or decrease the range of variation, the frequency of the variations, or other aspects. In some circumstances, producing components to tighter tolerances may increase production costs (or vice versa). For example, the tighter tolerance production processes may be more expensive than wider tolerance production processes. Tighter tolerance may result in more unsuitable components. Unsuitable components may be discarded without recovering production costs or repaired adding to production costs. Production processes may be modified to decrease or eliminate the production of unsuitable components, but in some circumstances this may increase costs. The described TEC may facilitate cost effective production of optoelectronic subassemblies in large quantities with suitable tolerance.

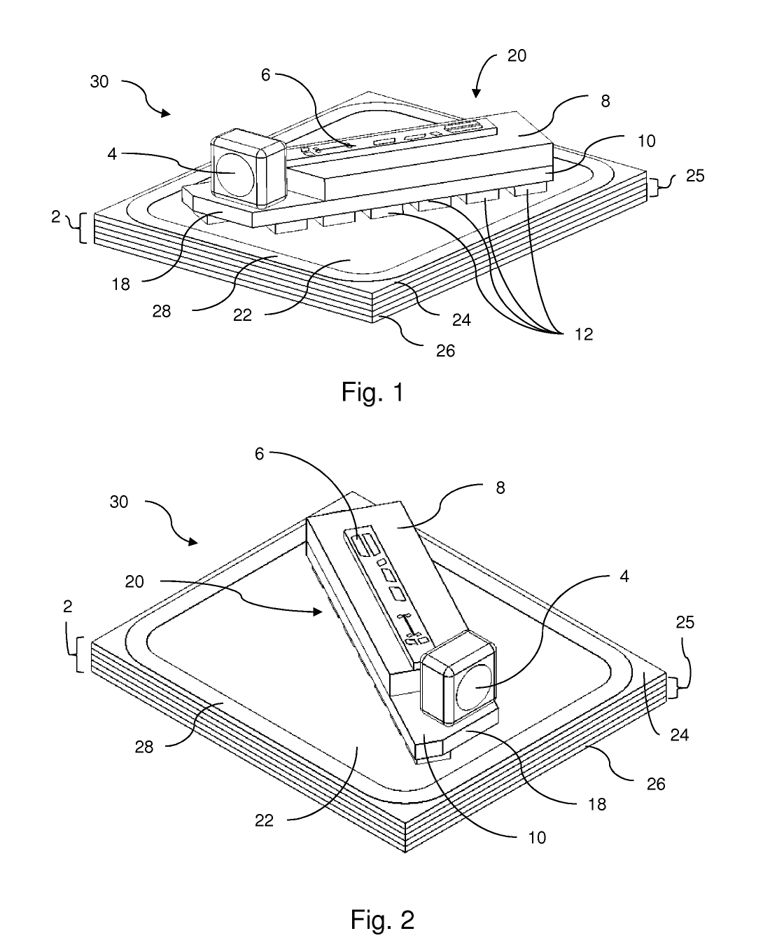

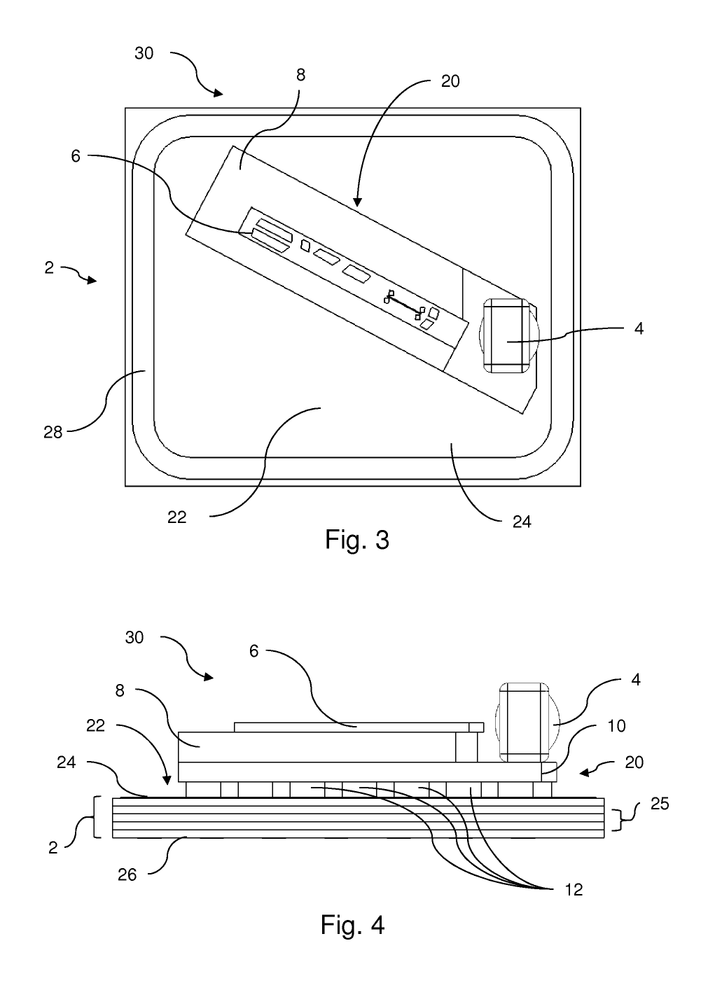

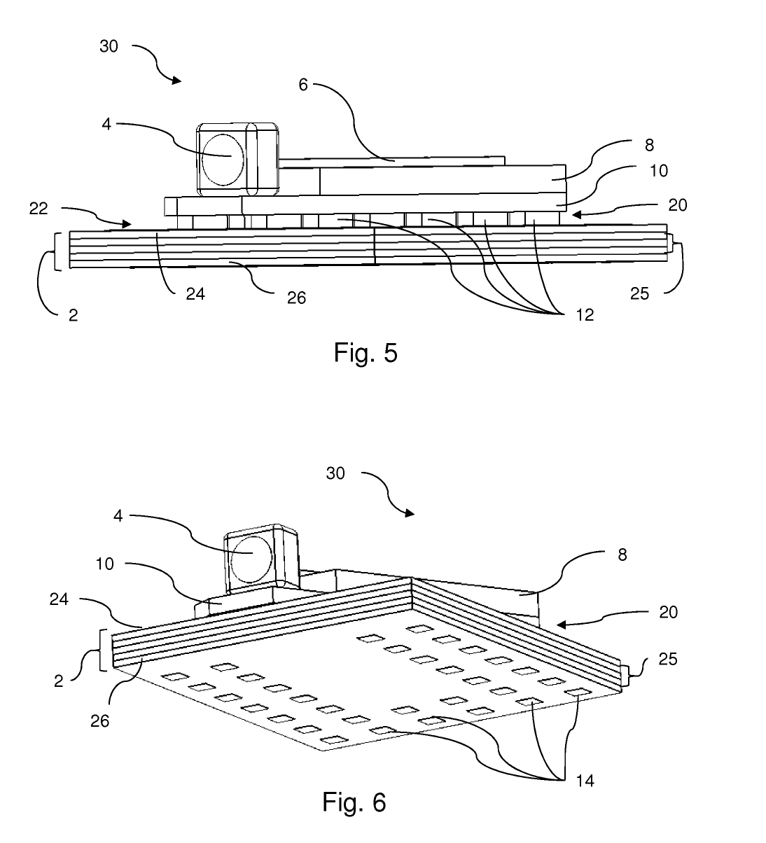

FIGS. 1-6 illustrate an example optoelectronic assembly 30. The optoelectronic assembly 30 may be configured to transmit and/or receive optical signals to and/or from a fiber optic network. Additionally or alternatively, the optoelectronic assembly 30 may be configured to convert electrical signals to optical signals and/or convert optical signals to electrical signals. The optoelectronic assembly 30 may include any suitable components that may be used in optoelectronic subassemblies such as TOSAs, ROSAs and/or other optoelectronic subassemblies.

The optoelectronic assembly 30 may include drivers, monitor photodiodes, integrated circuits, inductors, capacitors, receivers, receiver arrays, control circuitry, lenses, laser arrays, or any suitable optoelectronic components. The optoelectronic assembly 30 may include optical components such as prisms, lenses, mirrors, filters, or other suitable components. Some of the components may be electrically coupled to one another by signal lines, wire bonds, or other suitable interconnections. Additionally or alternatively, some of the components may be optically coupled to one another. In one configuration, if the optoelectronic subassembly 30 includes a TOSA it may include a laser assembly 6. Additionally or alternatively, if the optoelectronic subassembly 30 includes a ROSA it may include a receiver or a receiver array. In some configurations, the optoelectronic subassembly 30 may include both a TOSA and a ROSA and include both the laser assembly 6 and the receiver.

As illustrated, the optoelectronic assembly 30 can include a TEC 20 that is integrated with a substrate 2. The TEC 20 may facilitate controlling the temperature of the laser assembly 6 and/or other portions of the optoelectronic assembly 30. As will be described in further detail below, aspects of the optoelectronic assembly 30 and/or the TEC 20 may permit production of more compact optoelectronic assemblies including TEC's.

As illustrated, in some configurations the substrate 2 may be a multilayer substrate with multiple layers. For example, the multilayer substrate 2 may include one or more intermediate layers 25 between a top layer 24 and a bottom layer 26. In other configurations, the substrate 2 may include a single layer or may not be layered at all. Additionally or alternatively, the multilayer substrate 2 may include any suitable aspects of U.S. patent application Ser. No. 14/923,034 filed Oct. 26, 2015, entitled MULTI-LAYER SUBSTRATES and/or U.S. Provisional Application 62/069,710 filed Oct. 28, 2014, entitled MULTI-LAYER SUBSTRATES, which are both hereby incorporated by reference in their entirety.

As illustrated, the substrate 2 may be substantially rectangular. In alternative embodiments, the substrate 2 may be substantially round, oval, or any other suitable configuration. Some or all of the layers of the substrate 2 may include a material selected for various properties such as high thermal conductivity, electrical insulation, electrical conduction, cost, stability, heat tolerance or other properties. The material may be a ceramic material such as aluminum nitride or aluminum oxide, however, other suitable materials may also be used. At least a portion of the multi-layer substrate 2 may be formed of silicon, silicon dioxide, alumina, aluminum nitrate, aluminum oxide, sapphire, germanium, gallium arsenide, an alloy of silicon and germanium, or indium phosphide.

The substrate 2 can include a substrate surface 22 on the top layer 24. The substrate surface 22 may be adapted so components may be coupled to or formed on the substrate 2. For example, the substrate surface 22 may include a housing seat 28 shaped and/or dimensioned to couple with a housing or other components. In some configurations, the housing seat 28 may include a recessed portion to receive the housing or other components. In other configurations, the housing seat 28 may be positioned wherever the housing is coupled to the substrate surface 22. The housing seat 28 may be shaped and dimensioned to correspond with a base of the housing. As illustrated, the housing seat 28 includes a rectangular configuration with rounded corners. This rectangular configuration may correspond to the base of the housing, or vice versa. The housing seat 28 may include a suitable configuration such as circular, oval, multi-faceted or other configuration.

A TEC 20 may be mounted to the substrate surface 22 of the substrate 2. The TEC 20 can include one or more pillars 12 that may be positioned between the top layer 24 and a TEC top 10. In some configurations, the TEC 20 may be integrated with the substrate 2. In such configurations, the TEC 20 can be devoid of a TEC base or a TEC bottom body between the pillars and the top layer 24. For example, at least a portion of the substrate 2 may form a base of the TEC. In some configurations, the top layer 24 may form the base of the TEC 20. In another configuration, the top layer 24 and the intermediate layers 25 may form the base of the TEC 20. In yet another configuration, all of the layers of the substrate 2 may form the base of the TEC 20 including the top layer 24, the intermediate layers 25 and the bottom layer 26.

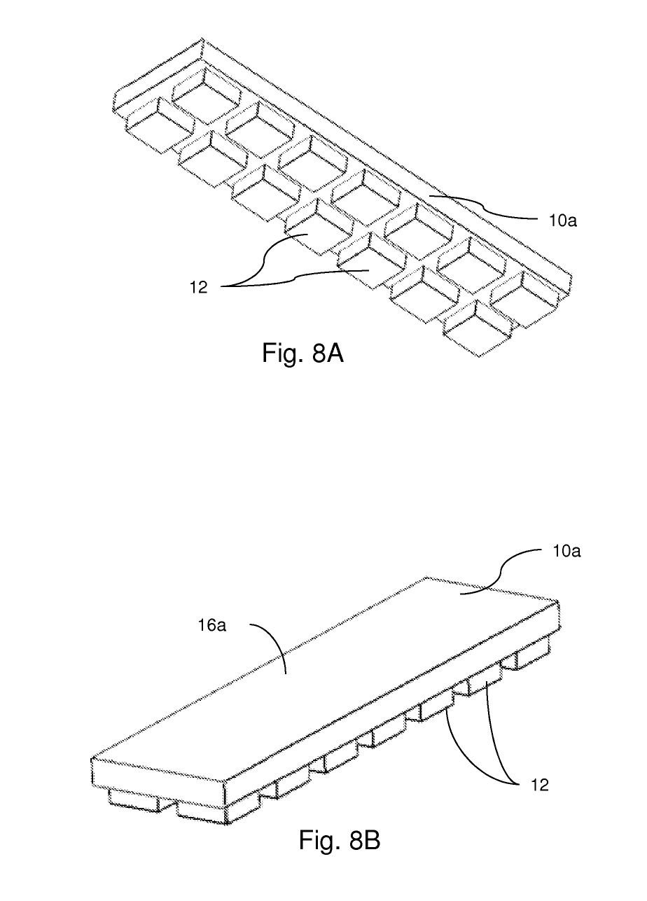

As illustrated for example in FIGS. 1 and 2, the TEC 20 may be positioned in an angled configuration with respect to the substrate 2. The TEC top 10 may include a truncated portion 18 that may accommodate the shape of the substrate 2. In alternative configurations, the TEC 20 may not include the angled configuration and/or the truncated portion 18 (see for example FIGS. 8A-8B). A submount 8 may be positioned on a portion of the TEC top 10 and the laser assembly 6 may be positioned on the submount 8. As illustrated, the submount 8 may be shaped and positioned to substantially align with a portion of the TEC top 10 (or vice versa). The submount 8 may or may not include a truncated portion corresponding to the truncated portion 18. In alternative configurations, the submount 8 and/or the TEC top 10 may be shaped or positioned in non-aligned configurations. In other configurations, the submount 8 may extend over the entire TEC top 10.

A lens 4 may be positioned on a portion of the TEC top 10 that does not include the submount 8. The lens 4 may be spaced apart from and/or optically coupled to the laser assembly 6. The lens 4 and the laser assembly 6 may be configured to direct optical signals from the optoelectronic assembly 30. In some configurations, the lens 4 may be positioned on the submount 8. In other configurations, other optoelectronic components may be positioned on the submount 8 and/or the TEC top 10.

In some configurations, the laser assembly 6 may include a tunable laser. In such configurations, the TEC 20 may facilitate temperature control of the tunable laser and/or components coupled to the tunable laser. Controlling the temperature of the tunable laser and/or coupled components may facilitate control of frequencies of optical signals emitted by the tunable laser. For example, the TEC 20 may be used to maintain the temperature of the laser assembly 6 around a specified temperature or range of temperatures so that the laser assembly 6 emits optical signals around a specified frequency or range of frequencies. The tolerance of the temperature range and/or frequency range may depend on the application of the optoelectronic assembly 30 and/or the laser assembly 6. In some configurations, the laser assembly 6 may be configured to emit optical signals of multiple wavelengths. In some configurations, the laser assembly 6 may be a multi-channel and/or a multi-wavelength tunable laser assembly.

As illustrated for example in FIG. 6, the optoelectronic assembly 30 may include contact pads 14 (only some of which are labeled in the Figures for clarity). The contact pads 14 may electrically couple the optoelectronic assembly 30 to other electronics. For example, the contact pads 14 may be capable of engaging flex circuits, printed circuit boards (“PCBs”), or other connectors and/or electronic assemblies. The contact pads 14 may be capable of transmitting electrical power and/or control signals to the optoelectronic assembly 30. For example, the contact pads 14 may permit electrical power and/or control signals to travel through the contact pads to vias and/or signal lines extending through a portion of the substrate 2, and then to optoelectronic components such as the laser assembly 6 and/or the TEC 20 (or other components). The electrical power and/or control signals may operate the laser assembly 6 and/or the TEC 20.

The contact pads 14 may include any suitable configurations other than those illustrated. For example, the contact pads 14 may include other quantities, other shapes, other dimensions and/or other positioning of the contact pads 14. In some configurations, power and control signals may not be transmitted through the contact pads 14 and may be transmitted to the optoelectronic assembly 30 through other suitable features or structures. Although the contact pads 14 may be formed of any suitable conductive material, in some examples the contact pads 14 may be formed of a metal such as silver (Ag), gold (Au), nickel (Ni), titanium (Ti), palladium (Pd), tungsten (W), tungsten-molybdenum (WMo) or other material. In some configurations, the contact pads 14 may be coupled to or integral with the bottom layer 26.

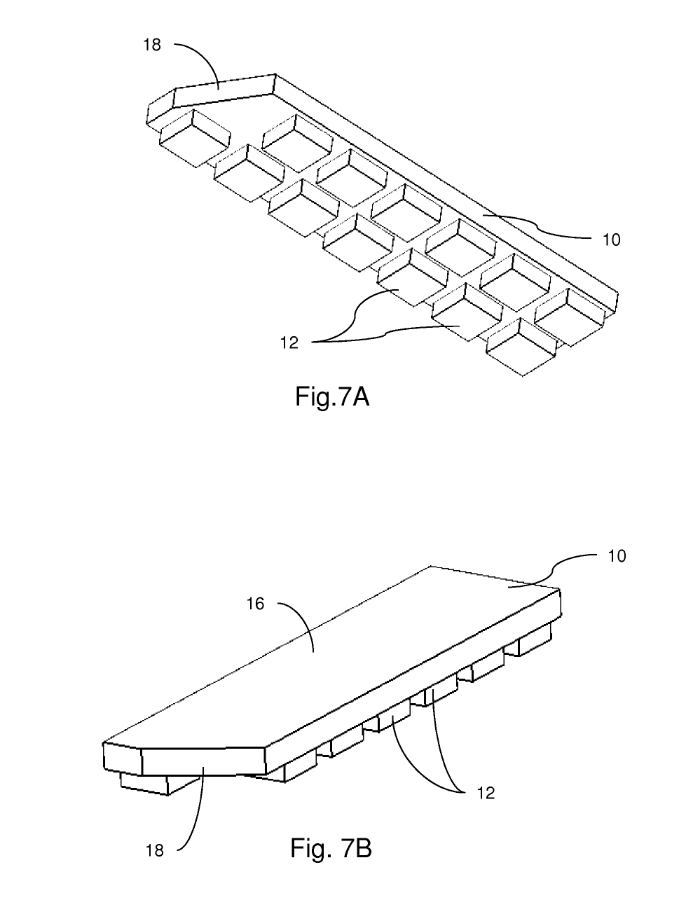

Turning to FIGS. 7A and 7B, a portion of the TEC 20 will be described in further detail. As illustrated, the TEC top 10 may be substantially rectangular with the truncated portion 18 positioned on one end. The pillars 12 may be coupled to or formed with the TEC top 10. The pillars 12 may include any suitable size and shape such as square or rectangular (as illustrated), circular, multi-faceted, and/or other configurations. As illustrated, the pillars 12 may include widths that are greater than the heights of the pillars 12. In some configurations, such proportions may contribute to the low profile of the TEC 20. In non-illustrated configurations, the heights of the pillars 12 may be greater than the widths of pillars 12.

Although in the illustrated configuration each of the pillars 12 are about the same size and shape (within acceptable tolerances), the pillars 12 may differ in dimension and/or shape from one another. For example, the pillars 12 may include heights, widths and/or shapes that differ from one another. Although in the illustrated example the pillars 12 include a substantially constant height, in other configurations the pillars 12 may include varying heights. For example, in some configurations at least one of the pillars 12 may include a linearly varying height such that the top and the bottom are sloped with respect to one another. In some configurations, all of the pillars 12 may include linearly varying heights such that the TEC top 10 may be sloped when coupled to the top layer 24 via the pillars 12.

As illustrated, some configurations of the TEC 20 may include thirteen (13) pillars 12. In alternative embodiments, the TEC 20 may include any suitable number of pillars 12. Furthermore, although FIG. 7A depicts two rows of pillars 12, in non-illustrated configurations there may be any suitable number of rows of pillars 12. For example, non-illustrated configurations may include one row of pillars 12, three rows of pillars 12, or any other suitable amount.

The TEC top 10 may include a component mounting surface 16. As illustrated, the component mounting surface may include a rectangular configuration interrupted by the truncated portion 18. Components such as the submount 8, the lens 4, and/or other components may be positioned on the component mounting surface 16. Additionally or alternatively, some components may be positioned on the submount 8 which is positioned on the component mounting surface 16.

The TEC top 10 may be formed of any suitable material such as a ceramic material. For example, the TEC top 10 may include and/or be formed of silicon, silicon dioxide, alumina, aluminum nitrate, aluminum oxide, aluminum nitride, beryllium oxide, sapphire, germanium, gallium arsenide, an alloy of silicon and germanium, or indium phosphide. The TEC top 10 material may be selected for various properties such as high thermal conductivity, electrical insulation, electrical conduction, cost, stability, heat tolerance or other properties.

The pillars 12 may be formed of any suitable material. For example, the pillars 12 may include and/or be formed of a thermoelectric material such as bismuth telluride, bismuth selenide, lead telluride, silicon germanium, bismuth-antimony, inorganic clathrate, skutterudite material, and/or a silicide. The material of one or more of the pillars may be selected for various properties such as thermoelectric performance, electrical conductivity, thermal conductivity, Seebeck coefficient, state density, material costs, production costs, complexity and/or other suitable properties.

The portion of the substrate 2 that forms part of the TEC 20 (such as the base of the TEC 20) may include and/or be formed of the same material as the TEC top 10. For example, the top layer 24 may be formed of the same material as the TEC top 10. In some configurations, the intermediate layers 25 and/or the bottom layer 26 may form part of the TEC 20. In such configurations, the intermediate layers 25 and/or the bottom layer 26 may form part of the base of the TEC 20. Accordingly, the top layer 24, the intermediate layers 25 and/or the bottom layer 26 may include and/or be formed of a ceramic material, silicon, silicon dioxide, alumina, aluminum nitrate, aluminum oxide, aluminum nitride, beryllium oxide, sapphire, germanium, gallium arsenide, an alloy of silicon and germanium, or indium phosphide.

As illustrated for example in FIGS. 8A-8B, in some configurations the truncated portion 8 may be omitted. In such configurations, the TEC top 10a may be rectangular and the component mounting surface 16a may be include a corresponding rectangular configuration (or vice versa). In some configurations, the submount 8 may be shaped and/or dimensioned to correspond to, or align with, the mounting surface 16a and/or the TEC top 10a. In some circumstances, omitting the truncated portion 8 may facilitate decreasing production costs for the TEC 20 and/or the optoelectronic assembly 30.

As illustrated for example in FIG. 4, configurations of the TEC 20 may result in a decreased height and/or a smaller profile of the optoelectronic assembly 30. Specifically, integrating the TEC 20 into the substrate 2 may result in the optoelectronic assembly 30 with a decreased height and/or a smaller profile. Additionally or alternatively, configuring the TEC 20 to be devoid of a TEC base or TEC bottom body may result in the TEC 20 and/or the optoelectronic assembly 30 including a decreased height and/or a smaller profile. Additionally or alternatively, omitting a TEC base or TEC bottom may result in the TEC 20 and/or the optoelectronic assembly 30 including a decreased height and/or a smaller profile. The decreased height and/or profile of the TEC 20 and/or the optoelectronic assembly 30 may contribute to decreasing production costs of the optoelectronic assembly 30. In some aspects, the configuration of the TEC 20 may result in components being positioned closer to the substrate 2. For example, the submount 8, the lens 4 and/or the laser assembly 6 may be positioned closer to the substrate 2 because the height of the TEC 20 is decreased because it is incorporated into the substrate 2. In some aspects, configurations of the TEC 20 may permit decreasing the size of a housing or hermetically sealed housing of the optoelectronic assembly 30. Additionally or alternatively, some aspects of the TEC 20 and/or the optoelectronic assembly 30 may permit the length of RF lines to be minimized.

The described configurations may facilitate production of the optoelectronic assembly 30 with a decreased height. Additionally or alternatively, the described configurations may facilitate production of the TEC 20 with a decreased height. The decreased height of the TEC may permit the submount 8 to be electrically coupled to other components such as the substrate 2 by shorter electrical couplings (e.g., wire bonds). Shorter electrical couplings may facilitate suitable RF performance. Accordingly, the described configurations may facilitate suitable RF performance.

In some configurations, some or all of the electrical couplings to the submount 8 may be wire bonds with a length between 1.0 millimeters (mm) and 1.1 mm. In some circumstances, wire bonds with a length between 1.0 mm and 1.1 mm may exhibit suitable RF performance characteristics. In some configurations, some or all of the electrical couplings to the submount 8 may be wire bonds with a maximum length of 1.2 mm. In some circumstances, wire bonds with a length less than 1.2 mm may exhibit suitable RF performance characteristics. In some configurations, some or all of the electrical couplings to the submount 8 may be wire bonds with lengths less than 1.2 mm.

In some configurations, the maximum distance between the submount 8 and the top layer 24 may be 0.9 mm. In some circumstances, wire bonds with suitable RF performance characteristics may be formed when the maximum distance between the submount 8 and the top layer 24 is 0.9 mm. In some configurations, the distance between the submount 8 and the top layer 24 may be less than 0.9 mm. In some circumstances, wire bonds with suitable RF performance characteristics may be formed when the distance between the submount 8 and the top layer 24 is less than 0.9 mm.

In some configurations, the height of the TEC 20 may be between 0.6 mm and 0.7 mm. In some circumstances, wire bonds with suitable RF performance characteristics may be formed when the height of the TEC 20 is between 0.6 mm and 0.7 mm. In some configurations, the height of the TEC 20 may be less than 0.7 mm. In some circumstances, wire bonds with suitable RF performance characteristics may be formed when the height of the TEC 20 is less than 0.7 mm.

In some configurations, the TEC top 10 may be the cool side of the TEC 10 and the top layer 24 of the substrate 2 may be the warm side of the TEC 10. In such configurations, the TEC 10 may be capable of decreasing the temperature or cooling parts of the optoelectronic subassembly 30 such as the laser assembly 6, the lens 4, and/or the submount 8.

In some configurations, a TEC can include a TEC top, a top layer of an optoelectronic subassembly substrate and a plurality of pillars extending between the TEC top and the top layer. In some configurations of the TEC, the TEC top is rectangular. In some configurations of the TEC, the TEC top can include a truncated portion.

In some configurations of the TEC, the pillars can be coupled to the TEC top. In some configurations, the pillars can be formed with the TEC top. In some configurations, at least one of the pillars can include a width greater than a height. In some configurations, each of the pillars include about a same size and shape. In some configurations, a first one of the pillars can differ in size and shape with a second one of the pillars. In some configurations, the pillars can include square, rectangular, circular, or multi-faceted configurations. In some configurations, the pillars can be arranged in rows. In some configurations, the pillars can be arranged in two rows.

In some configurations of the TEC, the TEC top can be formed of one or more of: a ceramic material, silicon, silicon dioxide, alumina, aluminum nitrate, aluminum oxide, aluminum nitride, beryllium oxide, sapphire, germanium, gallium arsenide, an alloy of silicon and germanium, or indium phosphide. In some configurations, at least one pillar can be formed of one or more of: bismuth telluride, bismuth selenide, lead telluride, silicon germanium, bismuth-antimony, inorganic clathrate, skutterudite material, and a silicide. In some configurations, the pillars include one or more of: bismuth telluride, bismuth selenide, lead telluride, silicon germanium, bismuth-antimony, inorganic clathrate, skutterudite material, and a silicide. In some configurations, the top layer can be formed of one or more of: a ceramic material, silicon, silicon dioxide, alumina, aluminum nitrate, aluminum oxide, aluminum nitride, beryllium oxide, sapphire, germanium, gallium arsenide, an alloy of silicon and germanium, or indium phosphide. In some configurations, the top layer can include the same material as the TEC top. In some configurations, the top layer can include a different material than the pillars.

In some configurations, the TEC top can be shaped and sized to align with a submount positioned over the TEC top. In some configurations, the TEC can be operably coupled to a laser assembly. In some configurations, the TEC can be operably coupled to a lens. In some configurations, the TEC can be devoid of a TEC bottom body between the pillars and optoelectronic subassembly substrate.

In some configurations, a TEC can include: a TEC top, a top layer of an optoelectronic subassembly substrate, and a plurality of pillars extending between the TEC top and the top layer, and the TEC can be devoid of a TEC bottom body (or a TEC base) between the pillars and optoelectronic subassembly substrate.

In some configurations, an optoelectronic assembly can include a TEC integrated with an optoelectronic subassembly substrate with: a TEC top, a top layer of the optoelectronic subassembly substrate, and a plurality of pillars extending between the TEC top and the top layer. In some configurations of the optoelectronic assembly, the TEC can be devoid of a TEC bottom body between the pillars and optoelectronic subassembly substrate.

In some configurations, the optoelectronic subassembly can include a submount over the TEC top. In some configurations, the submount can be sized and shaped to align with the TEC top. In some configurations, the optoelectronic subassembly can include a laser assembly over the submount or the TEC top. In some configurations, the optoelectronic subassembly can include a lens positioned on the TEC top. In some configurations of the optoelectronic subassembly, the lens can be optically coupled with the laser assembly. In some configurations of the optoelectronic subassembly, the optoelectronic subassembly substrate can include intermediate layers positioned between the top layer and a bottom layer.

In some configurations, the optoelectronic subassembly can include contact pads capable of transmitting electrical power and/or control signals. In some configurations of the optoelectronic subassembly, at least one of the contact pads can be electrically coupled to the TEC. In some configurations of the optoelectronic subassembly, at least one of the contact pads can be electrically coupled to an optoelectronic component.

In some configurations of the optoelectronic subassembly, the optoelectronic subassembly substrate can be rectangular. In some configurations of the optoelectronic subassembly, the TEC can be angled with respect to the optoelectronic subassembly substrate.

In some configurations of the optoelectronic subassembly, at least one of: the intermediate layers, the top layer and the bottom layer can include (or can be formed of or can be formed with) the same material as the TEC top. In some configurations of the optoelectronic subassembly, at least one of: the intermediate layers, the top layer and the bottom layer is formed of a different material than the pillars. In some configurations of the optoelectronic subassembly, at least one of: the intermediate layers, the top layer and the bottom layer includes a different material than the pillars. In some configurations of the optoelectronic subassembly, the TEC top is formed of a different material than the pillars.

In some configurations of the optoelectronic subassembly, the TEC top or the top layer can be formed of one or more of: a ceramic material, silicon, silicon dioxide, alumina, aluminum nitrate, aluminum oxide, aluminum nitride, beryllium oxide, sapphire, germanium, gallium arsenide, an alloy of silicon and germanium, and indium phosphide. In some configurations of the optoelectronic subassembly, the pillars or the top layer is formed of one or more of: bismuth telluride, bismuth selenide, lead telluride, silicon germanium, bismuth-antimony, inorganic clathrate, skutterudite material, and a silicide.

In some aspects, a method can include: providing a TEC top with a plurality of pillars extending from a bottom surface of the top; and coupling the pillars with a top layer of an optoelectronic subassembly substrate to form an integrated TEC.

In some aspects, the method can include forming the TEC top with one or more of: a ceramic material, silicon, silicon dioxide, alumina, aluminum nitrate, aluminum oxide, sapphire, germanium, gallium arsenide, an alloy of silicon and germanium, or indium phosphide. In some aspects, the method can include forming at least one of the pillars with one or more of: bismuth telluride, bismuth selenide, lead telluride, silicon germanium, bismuth-antimony, inorganic clathrate, skutterudite material, and a silicide. In some aspects, the method can include forming the top layer with one or more of: a ceramic material, silicon, silicon dioxide, alumina, aluminum nitrate, aluminum oxide, sapphire, germanium, gallium arsenide, an alloy of silicon and germanium, or indium phosphide. In some aspects, the method can include forming the top layer and the TEC top of a different material than the pillars. In some aspects, the method can include forming both the top layer and the TEC top with a same material.

In some aspects, the method can include forming a submount over at least a portion of the TEC top. In some aspects, the method can include coupling a submount with the TEC top. In some aspects, the method can include coupling a laser assembly with the TEC top or the submount. In some aspects, the method can include coupling a lens with the TEC top or the submount. In some aspects, the method can include optically coupling the lens with the laser assembly.

In some aspects, the method can include forming contact pads on a bottom layer of the substrate. In some aspects, the method can include electrically coupling at least one of the contact pads with the TEC. In some aspects, the method can include electrically coupling at least one of the contact pads with the laser assembly.

In some aspects of the method, the TEC can be devoid of a TEC bottom body between the pillars and optoelectronic subassembly substrate. In some aspects of the method, the TEC top can be rectangular. In some aspects of the method, the TEC top can include a truncated portion. In some aspects, the method can include coupling the pillars to the TEC top. In some aspects, the method can include forming the pillars with the TEC top. In some aspects of the method, at least one of the pillars can include a width greater than a height.

In some aspects, the method can include electrically coupling the TEC and the optoelectronic subassembly substrate. In some aspects, the method can include electrically coupling the submount and the optoelectronic subassembly substrate. In some aspects, the method can include electrically coupling the submount and the top layer. In some aspects, the method can include wirebonding the submount to the substrate surface.

The present disclosure may be embodied in other specific forms without departing from its spirit or essential characteristics. The described configurations are to be considered in all respects illustrative and not restrictive. The claimed subject matter is indicated by the appended claims rather than by the foregoing description. All changes that come within the meaning and range of equivalency of the claims are to be embraced within their scope.

What is claimed is:

1. A thermoelectric cooler (TEC) comprising:
a TEC top;
a top layer of an optoelectronic subassembly substrate; and
a plurality of pillars extending between the TEC top and the top layer.

2. The TEC of claim 1, wherein the TEC top is rectangular and includes a truncated portion and the pillars include square, rectangular, circular, or multi-faceted configurations.

3. The TEC of claim 1, wherein the top layer of the optoelectronic subassembly substrate includes the same material as the TEC top.

4. The TEC of claim 1, wherein:
the TEC top is formed of one or more of: a ceramic material, silicon, silicon dioxide, alumina, aluminum nitrate, aluminum oxide, aluminum nitride, beryllium oxide, sapphire, germanium, gallium arsenide, an alloy of silicon and germanium, or indium phosphide;
the pillars include one or more of: bismuth telluride, bismuth selenide, lead telluride, silicon germanium, bismuth-antimony, inorganic clathrate, skutterudite material, and a silicide; and
the top layer of the optoelectronic subassembly substrate is formed of one or more of: a ceramic material, silicon, silicon dioxide, alumina, aluminum nitrate, aluminum oxide, aluminum nitride, beryllium oxide, sapphire, germanium, gallium arsenide, an alloy of silicon and germanium, or indium phosphide.

5. The TEC of claim 1, wherein the TEC is devoid of a TEC bottom body positioned between the pillars and optoelectronic subassembly substrate.

6. An optoelectronic assembly comprising:
a thermoelectric cooler (TEC) integrated with an optoelectronic subassembly substrate, comprising:
a TEC top;
a top layer of the optoelectronic subassembly substrate; and
a plurality of pillars extending between the TEC top and the top layer.

7. The optoelectronic assembly of claim 6, wherein the TEC is devoid of a TEC bottom body between the pillars and optoelectronic subassembly substrate.

8. The optoelectronic assembly of claim 6, further comprising a submount over the TEC top, the submount sized and shaped to align with the TEC top.

9. The optoelectronic assembly of claim 8, further comprising:
a laser assembly over the submount or the TEC top; and
a lens positioned on the TEC top, the lens optically coupled with the laser assembly.

10. The optoelectronic assembly of claim 6, further comprising contact pads capable of transmitting electrical power and/or control signals, wherein at least one of the contact pads are electrically coupled to the TEC.

11. The optoelectronic assembly of claim 6, wherein the TEC is angled with respect to the optoelectronic subassembly substrate.

12. The optoelectronic assembly of claim 6, wherein the optoelectronic subassembly substrate includes intermediate layers positioned between the top layer and a bottom layer.

13. The optoelectronic assembly of claim 12, wherein:
the top layer includes the same material as the TEC top;
the top layer is formed of a different material than the pillars; and
the TEC top is formed of a different material than the pillars.

14. The optoelectronic assembly of claim 6, wherein:
the TEC top or the top layer is formed of one or more of: a ceramic material, silicon, silicon dioxide, alumina, aluminum nitrate, aluminum oxide, aluminum nitride, beryllium oxide, sapphire, germanium, gallium arsenide, an alloy of silicon and germanium, and indium phosphide; and
the pillars or the top layer is formed of one or more of: bismuth telluride, bismuth selenide, lead telluride, silicon germanium, bismuth-antimony, inorganic clathrate, skutterudite material, and a silicide.

15. A method comprising:
providing a thermoelectric cooler (TEC) top with a plurality of pillars extending from a bottom surface of the top; and
coupling the pillars with a top layer of an optoelectronic subassembly substrate to form an integrated TEC.

16. The method of claim 15, further comprising:
forming the TEC top or the top layer with one or more of: a ceramic material, silicon, silicon dioxide, alumina, aluminum nitrate, aluminum oxide, sapphire, germanium, gallium arsenide, an alloy of silicon and germanium, or indium phosphide; and
forming at least one of the pillars with one or more of: bismuth telluride, bismuth selenide, lead telluride, silicon germanium, bismuth-antimony, inorganic clathrate, skutterudite material, and a silicide.

17. The method of claim 15, further comprising forming both the top layer and the TEC top from the same material that is different than a material of the pillars.

18. The method of claim 15, further comprising:
positioning a submount over at least a portion of the TEC top;
coupling a laser assembly with the TEC top or the submount;
coupling a lens with the TEC top or the submount; and
optically coupling the lens with the laser assembly.

19. The method of claim 18, further comprising:
electrically coupling the TEC and the optoelectronic subassembly substrate; and
electrically coupling the submount and the optoelectronic subassembly substrate.

20. The method of claim 15, wherein the TEC is devoid of a TEC bottom body between the pillars and optoelectronic subassembly substrate.
